(19) United States
(12) Patent Application Publication
(10) Pub. No.: US 2020/0270122 A1
(43) Pub. Date: Aug. 27, 2020

(54) MULTI-CAVITY PACKAGE FOR ULTRASONIC TRANSDUCER ACOUSTIC MODE CONTROL

(71) Applicant: Chirp Microsystems, Inc., Berkeley, CA (US)

(72) Inventors: Stefon Shelton, Oakland, CA (US); Fabian Goericke, Berkeley, CA (US)

(21) Appl. No.: 16/872,712

(22) Filed: May 12, 2020

Related U.S. Application Data
(63) Continuation-in-part of application No. 15/987,824, filed on May 23, 2018.
Application No. 15/987,824 is a continuation of application No. PCT/US15/63242, filed on Dec. 1, 2015.

(51) Int. Cl. B81B 7/00; H04R 1/02; H04R 19/02; H04R 1/28; B06B 1/06; B81B 7/02

(52) U.S. Cl. CPC B81B 7/0061; B81B 2207/07; H04R 19/02; H04R 1/2888; B06B 1/0666; B06B 1/0681; B81B 7/02; H04R 2201/003; B81B 2201/0235; B81B 2201/0242; B81B 2201/0271; B81B 2203/0127; B81B 2203/0315; B81B 2207/015; H04R 1/025

(57) ABSTRACT

A micromechanical system (MEMS) device package comprising a substrate and a first enclosure including a first cavity, coupled to the substrate. Wherein a transverse dimension of the first cavity relative to the substrate is configured to reduce undesirable acoustic modes within the first cavity and the first cavity comprises an acoustic port. A MEMS device is located inside the first cavity and an Application Specific Integrated Circuit (ASIC) is communicatively coupled to the MEMS device and located outside the first cavity.

### CROSS-REFERENCE TO RELATED APPLICATION

This application is a continuation in part of commonly-assigned, co-pending application Ser. No. 15/987,824, filed May 23, 2018 the entire disclosures of which are incorporated herein by reference. Co-pending application Ser. No. 15/987,824, filed May 23, 2018 is a continuation of International Patent Application Number PCT/US15/63242 filed Dec. 1, 2015, the entire contents of which are incorporated herein by reference.

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### FIELD OF THE INVENTION

The present disclosure generally relates to packaging for micromachined ultrasonic transducers (MUTs) and more particularly to packaging design for a micromachined ultrasonic transducer implementing a design of the back cavity using multiple cavities to control the resonant acoustic modes of the cavity, thereby increasing transducer performance

### BACKGROUND OF THE INVENTION

Micromachined ultrasonic transducers (MUTs), and more specifically piezoelectric MUTs (pMUTs), typically consist of a released membrane structure operated at resonance and enclosed on one side by the package. In this type of structure, the design of the back-cavity on the enclosed side of the membrane has a strong effect on transducer performance, particularly the output pressure and bandwidth. Because typical packaging dimensions for MUTs are on the order of a wavelength for transducers operating at ultrasonic frequencies, standing waves are generated in the package back-cavity giving rise to acoustic resonant modes. With a traditional rectangular cavity, there are 3 degrees of freedom and multiple acoustic resonance modes in the x, y, and z dimensions as well as combination modes. The plurality of package acoustic resonance modes, if located at the incorrect frequency, can significantly reduce the output pressure and bandwidth of the transducer.

Additionally packages for MUTs include an Application Specific Integrated Circuit (ASIC) that may control the operation of the MUT. These ASICs are often located on the front side of the MUT. This layout creates a smaller back cavity for the MUT but with a larger overall device thickness. Thick devices are undesirable for many modern applications as reduced width is an increasingly popular selling point. Other devices include the ASIC in the same back cavity as the MUT but this increases the size of the back-cavity, which may also encourage the propagation of standing waves due the size of the back cavity relative to the ultrasonic frequencies. In order to ensure device performance across a range of frequencies and temperatures, a method of controlling the resonant modes of the cavity is required.

### BRIEF DESCRIPTION OF THE DRAWINGS

The teachings of the present disclosure can be readily understood by considering the following detailed description in conjunction with the accompanying drawings, in which:

FIG. 1 shows a cross section of an ultrasonic transducer package having a cylindrical back-cavity in accordance with an aspect of the present disclosure.

FIG. 2 is an isometric view of an ultrasonic transducer package having a cylindrical back-cavity in accordance with an aspect of the present disclosure.

FIG. 3 shows a cross section of an ultrasonic transducer package having a hemispherical back-cavity in accordance with an aspect of the present disclosure.

FIG. 4 is an isometric view of an ultrasonic transducer package having a hemispherical back-cavity in accordance with an aspect of the present disclosure.

FIG. 5 shows the acoustic frequency response of a pMUT with a 165 kHz operating frequency that is packaged in an ultrasonic transducer package with a rectangular back-cavity.

FIG. 6 shows the acoustic frequency response of a pMUT with a 165 kHz operating frequency that is packaged in an ultrasonic transducer package with a cylindrical back-cavity.

FIG. 7 shows the acoustic frequency response of a pMUT with a 165 kHz operating frequency that is packaged in an ultrasonic transducer package with a hemispherical back-cavity.

FIG. 8 shows the acoustic frequency response of a pMUT with a 165 kHz operating frequency comparing the response when the back-cavity is rectangular, cylindrical, and hemispherical.

FIG. 9 shows a conventional large cavity Micro-Electro Mechanical System (MEMS) device package.

FIG. 10 depicts the frequencies at which standing waves are generated in the prior art large cavity device packages.

FIG. 11 shows a three-quarters view of a micromechanical (MEMS) device package according to aspects of the present disclosure.

FIG. 12A depicts a side view of a MEMS device package according to aspects of the present disclosure.

FIG. 12B shows an alternative embodiment of the MEMS Device package having a single metal lid enclosure according to aspects of the present disclosure.

FIG. 12C shows an alternative embodiment of the MEMS Device package having a single lid enclosure according to aspects of the present disclosure.

FIG. 12D depicts an alternative embodiment of the MEMS device package having a first lid enclosure and a second lid enclosure made from molding compound

FIG. 12E depicts yet another alternative embodiment of the MEMS device package made using a combination of molding compound and metal according to aspects of the present disclosure.

FIG. 12F depicts an alternative embodiment of the MEMS device package having a first enclosure and a second enclosure made from a combination of molding compound and metal according to aspects of the present disclosure.

FIG. 12G shows another alternative embodiment of the MEMS device package made from a composite material according to aspects of the present disclosure.

FIG. 12H depicts a MEMS device package having a first and second enclosures made from different materials according to alternative aspects of the present disclosure.

FIG. 13A shows a top down view of a single enclosure MEMS device package with round cavity for the MEMS device according to an aspect of the present disclosure.

FIG. 13B shows a top down view of a two-enclosure MEMS device package with round cavity and enclosure for the MEMS device according to an aspect of the present disclosure.

FIG. 14A depicts a side view of a two-enclosure MEMS device package with hemispherical cavity and enclosure according to aspects of the present disclosure.

FIG. 14B depicts a side view of a single enclosure MEMS device package with hemispherical cavity and enclosure according to aspects of the present disclosure.

FIG. 14C depicts a side view of a two-enclosure MEMS device package with hemispherical cavity and an infill cavity according to aspects of the present disclosure.

FIG. 14D depicts a side view of a two-enclosure MEMS device package with two hemispherical cavities and enclosure according to aspects of the present disclosure.

FIG. 14E depicts a side view of a single dome-topped enclosure MEMS device package with two hemispherical cavities and enclosure according to aspects of the present disclosure.

### SUMMARY OF THE INVENTION

Aspects of this disclosure relate to the package design for a pMUT utilizing curved geometry to control the presence and frequency of acoustic resonant modes in the back cavity of the transducer package. The approach involves reducing in number and curving the reflecting surfaces present in the package cavity. Utilizing, by way of example, cylindrical or spherical geometry the resonant acoustic modes present in the package are reduced and can be adjusted to frequencies outside the band of interest.

Additional Aspects of the present disclosure relate to package design for Micro-Electro Mechanical System (MEMS) devices including a pMUT that have separate cavities for the MEMS device and support circuitry. The reduced size of the cavity housing the MEMS device by way of excluding support circuitry further controls the presence and frequency of acoustic resonant modes in the back cavity of the transducer package.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention.

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In the interest of clarity, not all of the routine features of the implementations described herein are shown and described. It will be understood by those skilled in the art that in the development of any such implementations, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of the present disclosure.

In accordance with aspects of the present disclosure, the components, process steps, and/or data structures may be implemented using various types of operating systems; computing platforms; user interfaces/displays, including personal or laptop computers, video game consoles, PDAs and other handheld devices, such as cellular telephones, tablet computers, portable gaming devices; and/or general purpose machines. In addition, those of ordinary skill in the art will recognize that devices of a less general purpose nature, such as hardwired devices, field programmable gate arrays (FOGs), application specific integrated circuits (ASICs), or the like, may also be used without departing from the scope and spirit of the inventive concepts disclosed herein.

Aspects of this disclosure include a micromachined ultrasonic transducer (MUT) package, in particular a pMUT package comprised of a curved cavity to reduce the number of resonance modes present in the back cavity of a pMUT package. It will be appreciated that the following embodiments are provided by way of example only, and that numerous variations and modifications are possible. For example, while cylindrical and hemispherical embodiments are shown, the back cavity may have many different shapes utilizing curved geometry. Furthermore, while pMUTs are shown in this description, other MUTs should also be considered, such as capacitive micromachined ultrasonic transducers (cMUTs) or optical acoustic transducers. All such variations that would be apparent to one of ordinary skill in the art are intended to fall within the scope of this disclosure. It will also be appreciated that the drawings are not necessarily to scale, with emphasis being instead on the distinguishing features of the package with curved geometry for a pMUT device disclosed herein.

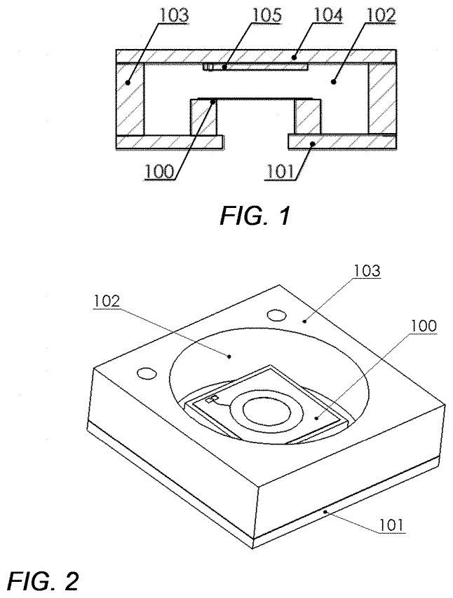

FIG. 1 illustrates a cylindrical example of the proposed pMUT package. In this embodiment the thin membrane pMUT 100 is mounted to a substrate 101 with a port hole for the sound to enter and exit. The cylindrical back-cavity 102 portion of the package may be enclosed by a protective lid composed of a spacer 103 and bottom substrate 104. Spacer 103 and bottom substrate 104 may be formed from laminate material such as FR-4 or BT (Bismaleimide/Triazine). Spacer 103 has a curved, e.g., circular or nearly circular or ellipsoidal hole that forms a curved cylindrical, e.g., circular or nearly circular or ellipsoidal cylindrical cavity for the transducer to sit in, as illustrated in FIG. 2. The bottom substrate 104 is then used to complete the cylindrical geometry. In some implementations, the protective lid may be made from a single piece and composed of stamped or formed metal or a molded polymer such as liquid crystal polymer (LCP). The radius of the cylindrical back-cavity is in the range of 0.2 mm to 5 mm, and more specifically 0.3 mm to 2.5 mm, for transducers operating at frequencies from 100 kHz to 600 kHz. Similarly, the height of the cylindrical back-cavity is in the range from 0.1 mm to 2 mm and more specifically in the range from 0.4 mm to 1 mm.

In some implementations, an application specific integrated circuit (ASIC) 105 may be mounted on bottom substrate 104 and electrical connections to the ASIC 105 and pMUT 100 may be provided through the bottom substrate 104, a configuration that is known as a top-port package since the acoustic port hole is located on substrate 101 opposite the bottom substrate 104. In other embodiments, the electrical connections may be provided through substrate 101, a configuration known as a bottom-port package since the electrical connections and the acoustic port are both located on a common substrate 101.

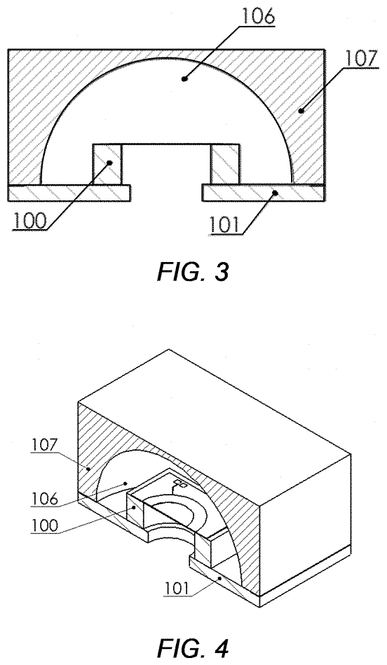

FIG. 3 shows a cross-section illustration of a hemispherical embodiment of the proposed package. In this embodiment, a pMUT 100 is mounted to a substrate 101 with a port hole for the ultrasound to enter and exit. A back-cavity 106 in this case is a hemisphere formed by a protective lid 107 which may be comprised of a metal, laminate, plastic, or other material. FIG. 4 shows a cut-away view of a hemispherical embodiment of a package. The radius of the hemispherical back-cavity is in the range of 0.2 mm to 3 mm, and more specifically 0.3 mm to 2 mm, for transducers operating at frequencies from 100 kHz to 600 kHz.

Given that typical packaging dimensions for MUTs are on the order of a wavelength at ultrasonic frequencies, standing wave patterns are generated in the package cavity that result in acoustic resonant modes. With a traditional rectangular cavity, there are 3 degrees of freedom and multiple acoustic resonance modes in the x, y, and z dimensions as well as combination modes.

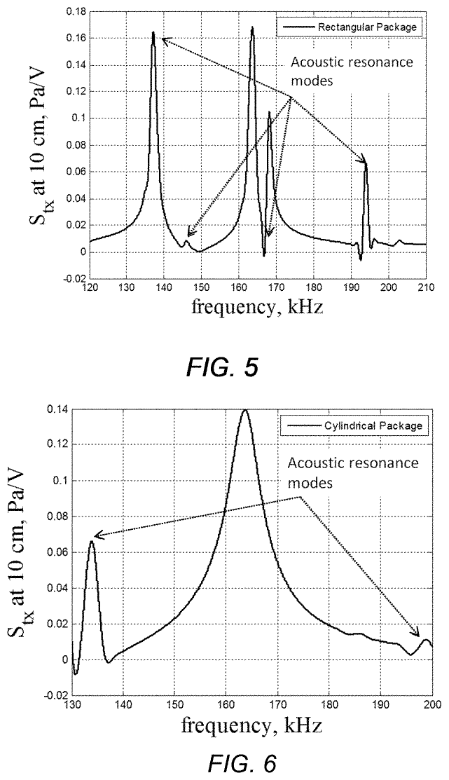

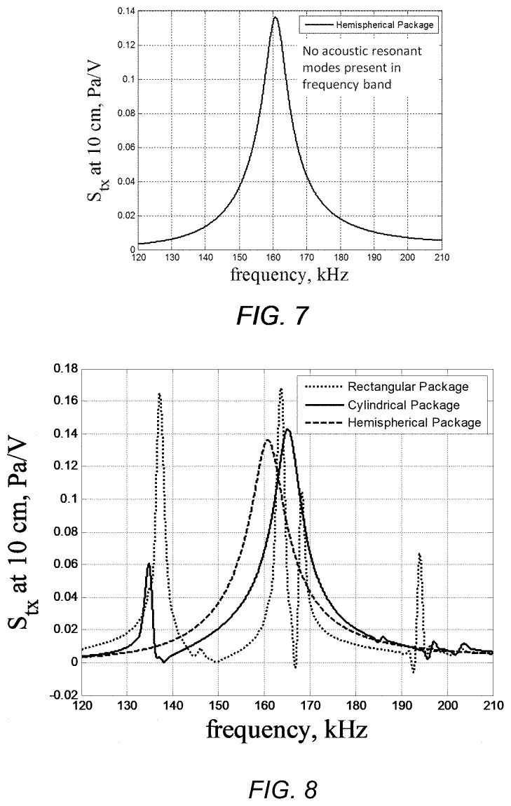

Back-cavities with rectangular geometry possess many different acoustic modes due to the plurality of reflecting surfaces. By way of example, but not limitation, the simulated acoustic frequency response of a 165 kHz pMUT packaged with a rectangular back-cavity is shown in FIG. 5. The transmit sensitivity (Pa/V), which is a measure of the output pressure per input volt, is calculated at 10 cm from the substrate port opening. When operating at the resonance frequency of the back-cavity, energy is transferred preferentially into the back-cavity resonance mode, causing the output pressure of the transducer to drop and having a deleterious effect on the transducer's frequency and time response. In this design example there are 4 acoustic resonance modes present in the back-cavity, one of which is at a frequency near the pMUT's 165 kHz resonance frequency. Because there are three other modes that lie at frequencies below (—137 kHz and ˜146 kHz) and above (˜195 kHz) the pMUT's 165 kHz operating frequency, it is very difficult to design a rectangular back-cavity where the acoustic resonance modes do not interfere with the PMUT's operating frequency, particularly when the effects of temperature on the resonance modes are taken into consideration. By curving the back-cavity geometry we reduce the number of acoustic paths that give rise to resonances thus flattening the acoustic frequency response. By way of example, but not limitation, cylindrical geometry reduces the number of degrees of freedom from three (xyz) to two (radius and height), thereby reducing the number of acoustic resonances in a given frequency band. FIG. 6 and FIG. 7 show the acoustic frequency response for a 165 kHz pMUT with a cylindrical and spherical back-cavity, respectively. It can be clearly seen that the number of acoustic resonances is significantly reduced for both geometries and any remaining modes are widely spaced in frequency. FIG. 8 shows a comparison between the frequency response of the ultrasonic transducer packaged with rectangular, cylindrical, and hemispherical back-cavities. The frequency response of the transducer packaged with a rectangular back-cavity exhibits an undesired null near 165 kHz whereas the transducer packaged with a cylindrical or hemispherical back-cavity shows the desired acoustic response at the pMUT's resonant frequency (˜165 kHz) with a full-width-at-half-maximum (FWHM) bandwidth of 10 kHz. This figure demonstrates that by carefully choosing the radius and height of the cylindrical cavity, we can shift the frequency of the back-cavity's acoustic resonance modes so that they do not interfere with the pMUT's operating frequency. Similarly, for the hemispherical embodiment, by careful selection of the hemispherical back-cavity's radius we can control the frequency of the resonant modes and locate them at frequencies chosen to enhance transducer performance.

Aspects of this disclosure include a micromachined ultrasonic transducer (MUT) package, in particular a pMUT package comprised of a cavity for the pMUT with an ASIC located on the same substrate outside the cavity for the MUT to reduce the number of resonance modes present in the back cavity of a pMUT package. It will be appreciated that the following embodiments are provided by way of example only, and that numerous variations and modifications are possible. For example, while cylindrical and hemispherical embodiments are shown, the back cavity may have many different shapes utilizing curved geometry. Furthermore, while pMUTs are shown in this description, other MUTs should also be considered, such as capacitive micromachined ultrasonic transducers (cMUTs) or optical acoustic transducers. All such variations that would be apparent to one of ordinary skill in the art are intended to fall within the scope of this disclosure. It will also be appreciated that the drawings are not necessarily to scale, with emphasis being instead on the distinguishing features of the package with curved geometry for a pMUT device disclosed herein.

MEMS Package with Separate Cavities

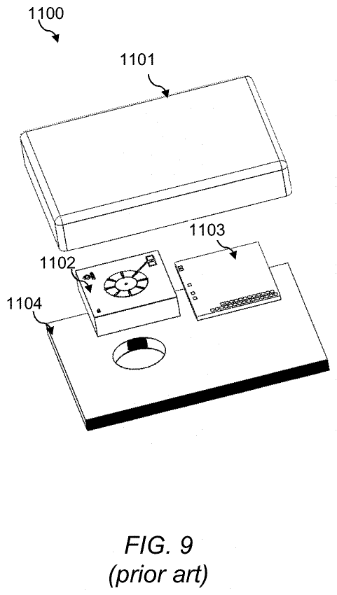

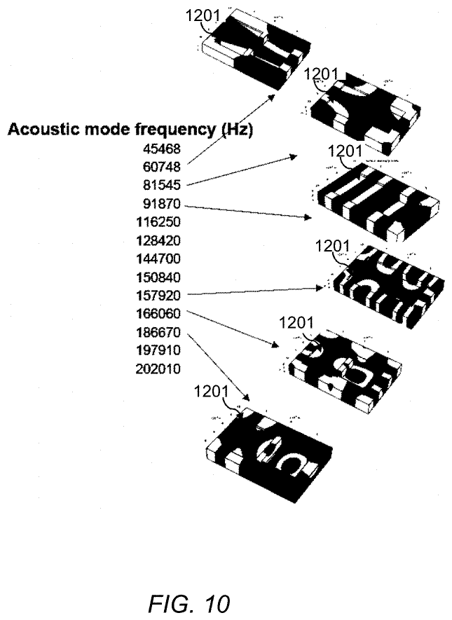

FIG. 9 shows a conventional MUT package. As shown the enclosure 1101 covers both the MUT 1102 and the ASIC 1103 in the same cavity. The MUT 1102 and the ASIC 1103 also share the same substrate 104. This prior art package has a reduced thickness because the enclosure 1101 and cavity is not required accommodate the thickness of both the MUT 1102 and ASIC 1103 stacked atop one another. Despite this, the prior art device package 1100 suffers from standing wave generation as shown in FIG. 10. It has been found that the size of the cavity that includes a MUT 1102 and ASIC 1103 mounted to the same substrate is close to wavelengths of ultrasonic sound generated by the MUT 1102.

FIG. 10 shows standing wave patterns generated in prior art large cavity device packages 1201 at several different frequencies. As shown standing waves are generated at 60748 Hz, 81545 Hz, 91870 Hz, 157920 Hz, 166060 Hz, 186670 Hz, the standing waves propagate through the package and cause harmful interference with acoustic signals generated by the MUT.

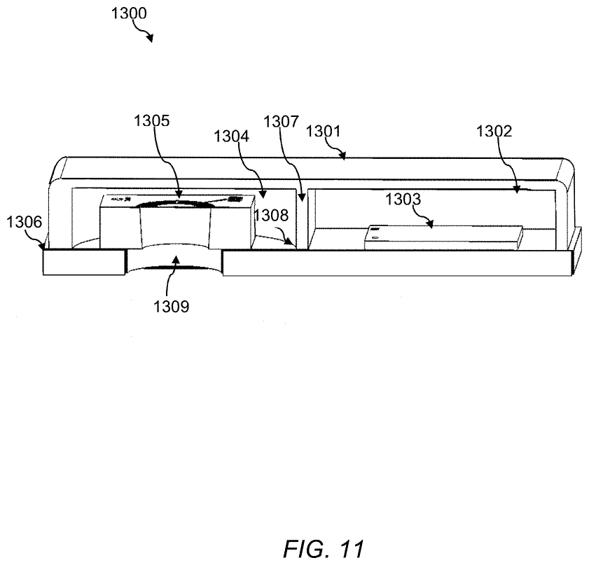

FIG. 11 shows a Micro-Electro Mechanical System (MEMS) device package 1300 according to aspects of the present disclosure. The device package 300 may include a single enclosure 1301 that has two separate cavities 1302, 1304. The enclosure 1301 may have a first cavity 1304 with a MEMS device 1305 such as a MUT located inside the first cavity 1304. The enclosure 1301 may also have a second cavity 1302 with an ASIC 1303 located inside the second cavity 1302. The first cavity 1304 and the second cavity 1302 may be separated by a partition wall 1307 made from the enclosure material. The ASIC 1303 and the MEMS device 1305 may be coupled to the same substrate 1306. The ASIC 1303 and the MEMS device 1305 may be attached to the substrate 1306 by attachment means such as solder, a bracket, epoxy adhesive, silicone adhesive or other low modulus of elasticity adhesive. Additionally, the MEMS device 1305 and the ASIC 1303 may be communicatively coupled to each other. For example and without limitation the ASIC 1303 and the MEMS device 1305 may be communicatively coupled through a metal trace in the substrate 1306 or through a via in the wall of the enclosure 1301, bond wires may connect the ASIC or the MEMS device to the traces. The effect of having a separate cavity for the MEMS device 1304 is to reduce the size of the back cavity. The MEMS device 1304 may be placed over an acoustic port 1309 opening in the cavity. The acoustic port 1309 opening runs through the substrate 1306 to the other-side of the substrate and allows sound waves to escape from the cavity. The back cavity size may be reduced to the point where undesirable acoustic modes (such as standing waves) no longer occur within the cavity. This size may be chosen such that the transverse dimension of the cavity 1304 relative to the substrate reduces standing wave reflections of wavelengths corresponding to a characteristic frequency of a mode of oscillation of the MEMS device. For example and without limitation the size of the first cavity 1304 may be sufficiently small compared to a wavelength of a characteristic frequency of oscillation of the MEMS device (e.g. less than 1 millimeter in width or diameter) that resonances in the frequency range of interest are sufficiently attenuated. Additionally as shown, to further reduce propagation of standing waves the walls of the first cavity 1304 may be curved 1308 to create a cylindrical cavity shape. The shape of the walls of the first cavity may be such that a cross section of the first cavity has a constant radius with respect to the height.

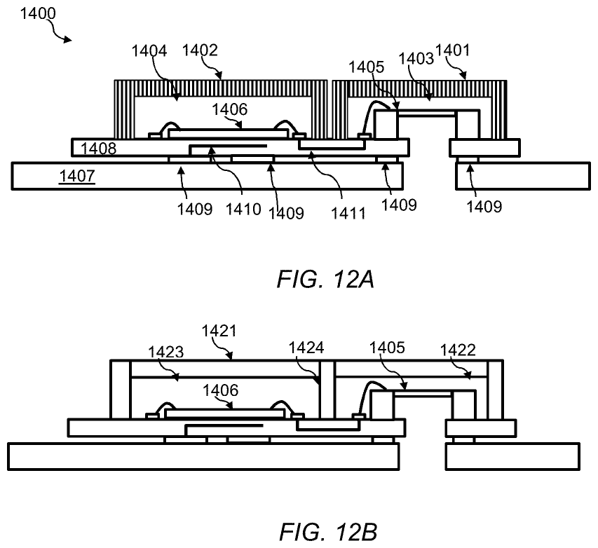

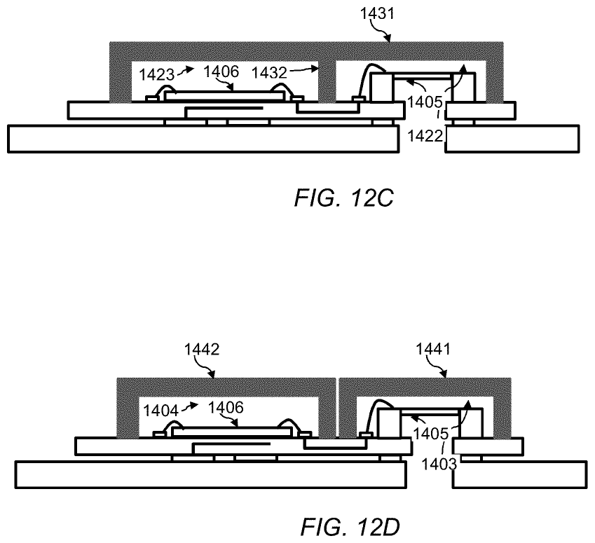

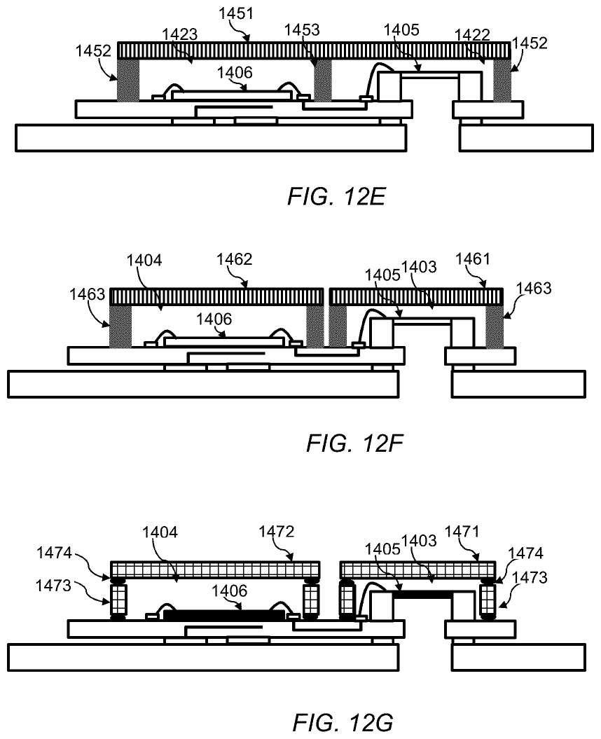

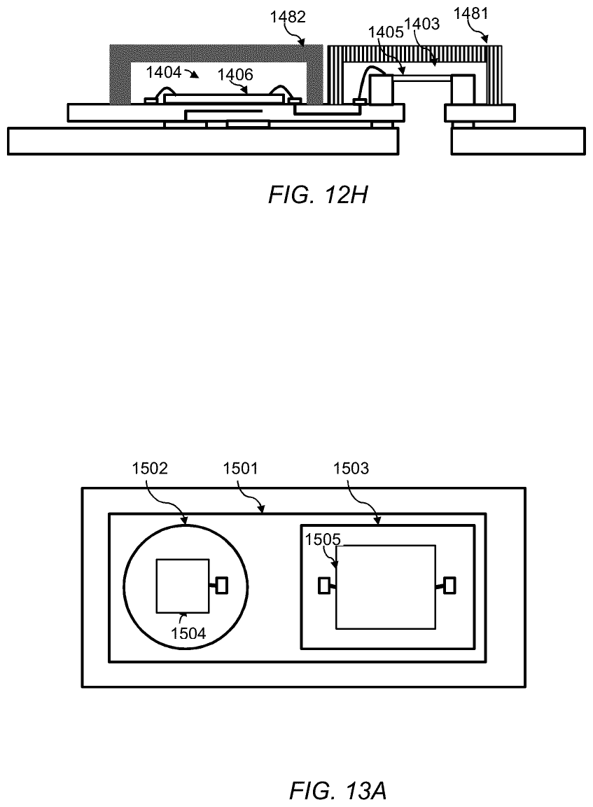

FIG. 12A depicts a side view of a MEMS device package according to aspects of the present disclosure. In the embodiment shown the MEMS device package 1400 includes a first enclosure 1401 and a second enclosure 1402. Each of the enclosures 1401, 1402 are metal lids having metal sides and a metal cap. For example, the metal lids may be made of aluminum, steel, iron, magnesium, copper, zinc or an alloy thereof. The metal lids 1401, 1402 may be attached to the substrate 1408. For example, and without limitation, the metal lid or lids may be attached to the substrate with clips, soldered to the substrate, glued to the substrate, etc. As shown, there may be a metal lid enclosure for the MEMS device 1401 and a separate metal lid enclosure for the ASIC 1402. The enclosure for the MEMS device 1401 has a cavity 1403 in which the MEMS device 1405 is located. While the depicted embodiments include a hemispherical cavity for MEMS device 1405, aspects of the present disclosure are not so limited and the shape of the cavity 1403 may be any shape includes quadrilateral parallelepiped or an irregular shape. The enclosure for the ASIC 1402 has a cavity 1404 in which the ASIC 1406 is located. Additionally, other components such as support circuitry for the MEMS device 1405 and the ASIC 1406 or gyroscopes or accelerometers or any combination thereof may be located in the cavity 1404 of the enclosure for the ASIC 1404. The first and second enclosures may be located a substantial distance away from each other for example and without limitation greater than 1 millimeter away.

As shown, the ASIC 1406 is communicatively coupled 1411 to the MEMS device 1405, bond wires may connect MEMS device and the ASIC to metal traces or wires through the substrate. The ASIC 1406 may communicate with the MEMS device 1405 by sending messages through a metal trace or wire 1411 on the substrate 1408. In one embodiment, Additionally, the messages sent by the ASIC 1406 and the MEMS device 1405 may pass through passive devices such as resistors and diodes without alteration of the content of the communication and as such are the ASIC and the MEMS device are communicatively coupled. The ASIC 1406 may also be communicatively coupled to other components in a system through a metal trace or wire 1410. The substrate 1408 may be conductively coupled to a circuit board or FLEX circuit 1407 of the system with solder, pin headers and pins, or other attachment means 1409. The metal trace or wire 1410 may run through the attachment means 1409 or communication may pass through the attachment itself 1409.

FIG. 12B shows an alternative embodiment of the MEMS Device package, having a single metal lid enclosure according to aspects of the present disclosure. In this embodiment, the MEMS device package includes a single metal lid enclosure 1421 housing both the MEMS device 1405 and the ASIC 1406. The metal lid enclosure 1421 includes a first cavity 1422 where the MEMS device 1405 is located and a second cavity 1423 where the ASIC 1406 is located. The metal lid enclosure includes a separator wall 1424 that may be made of a metal or molding material. The separator wall 1424 may be attached to the metal lid enclosure, for example and without limitation, it may be welded, soldered, clipped or glued to one or more surfaces on the cavity side of the metal lid enclosure 1421. Alternatively, the separator wall 1424 may be attached to the substrate, for example and without limitation, the separator wall may be soldered or glued to the surface of the substrate. In some cases, there may be more than one separator wall between the MEMS device and the ASIC but the single enclosure is divided into at least one cavity having the MEMS device and one cavity having the ASIC.

FIG. 12C shows an alternative embodiment of the MEMS Device package, having a single lid enclosure according to aspects of the present disclosure. As shown the MEMS Device package includes a single lid enclosure 1431 made from molding compound. The lid enclosure has sides and a top made from molding compound. A single separator wall or multiple separator walls 1432 that separate the first cavity 1403 having the MEMS device 1405 located within from the second cavity 1404 having the ASIC 1406. The molding compound may be any plastic, rubber or epoxy resin that has sufficient strength to retain its shape once cured. The molding compound may be impregnated with different property enhancing materials such as fiberglass, carbon fiber, glass beads etc. Similarly, FIG. 12D depicts an alternative embodiment of the MEMS device package having a first lid enclosure 1441 and a second lid enclosure 1442 made from molding compound.

FIG. 12E depicts yet another alternative embodiment of the MEMS device package, according to aspects of the present disclosure. In this embodiment, the MEMS device package includes a single enclosure having a metal cap 1451 and molded sides 1452. The molded sides 1452 may be made from molding compound formed on the surface of the substrate. The metal cap 1451 may be coupled to the molded sides 1452 through friction fitting of the cap 1451 to the molded sides 1452 during curing of the molded sides 1452. Alternatively, the metal cap 1451 may be attached to the molded sides 1452 with glue, screws or other attachment means. The single enclosure may include a separator wall 1453 between the first cavity 1422 having the MEMS device 1405 and the second cavity 1423 having the ASIC 1406. The separator wall 1453 may be made from molding compound and formed on the surface of the substrate. Alternatively, the separator wall 1453 may be made from metal and attached to the metal cap 1451 with, for example and without limitation, welds, soldering, glue, screws or the like. Similarly, FIG. 12F depicts an alternative embodiment of the MEMS device package having a first enclosure and a second enclosure. The first enclosure includes a first cavity 1403 having the MEMS device 1405 located therein. The first enclosure has a metal cap 1461 with molded sides 1463. The second enclosure includes a second cavity 1404 having the ASIC 1406 located therein. The second enclosure has a metal cap 1462 and molded sides 1463.

FIG. 12G shows another alternative embodiment of the MEMS device package according to aspects of the present disclosure. Here, the MEMS device package includes a first enclosure 1471 having the first cavity 1403 with the MEMS device 1405 and a second enclosure 1472 having the second cavity 1404 with the ASIC 1406; both enclosures are made from a composite material. The first enclosure 1471 may have a top and sides 1473 made from the composite material and the top and sides may be soldered or glued together 1474. Similarly, the second enclosure 1472 may have a top and sides 1473 made from the composite material and the top and sides may be soldered or glued together 1474. The composite material may be any material suitable for use with electronics such as BT, FR4, G-10, FR-2, etc. The composite material may include a copper or other metal laminate layer for ease of connection and use with other materials.

FIG. 12H depicts a MEMS device package according to alternative aspects of the present disclosure. This MEMS device package includes a first enclosure 1481 made from a different material than the second enclosure 1482. As shown the first enclosure 1481 is a metal lid whereas the second enclosure 1482 is a molded lid. Any of the above-described materials may be used in mixed combination as shown. For example, and without limitation the first enclosure may be any of molded lid, a metal cap with molded sides, or a composite lid in combination with the second enclosure which may be any of a molded lid, a metal cap with molded sides or a composite lid.

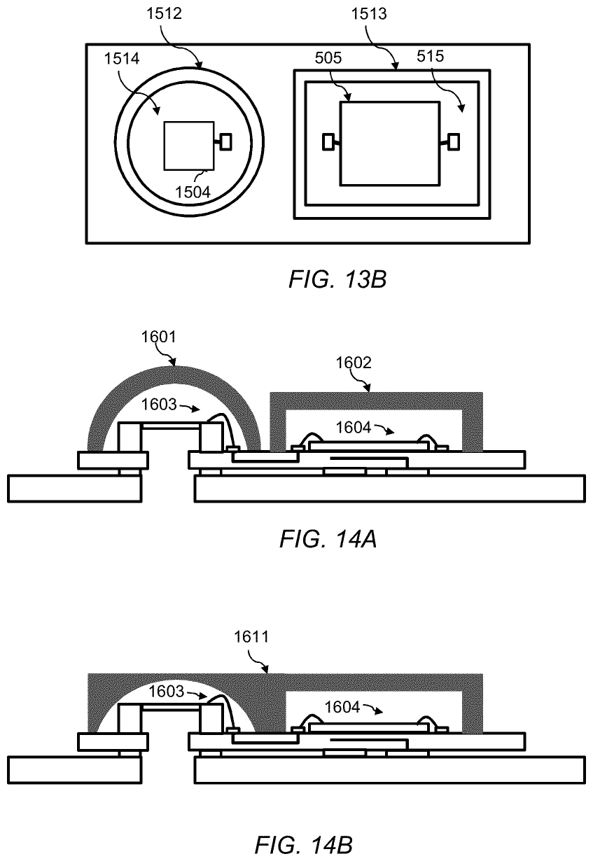

FIG. 13A shows a top down view of a single enclosure MEMS device package with round cavity for the MEMS device according to an aspect of the present disclosure. As shown the single enclosure 1501 includes a first cavity 1502 with a MEMS device 1504 located therein and a second cavity 1503 with the ASIC 1505 located therein. The first cavity 1502 has a substantially circular cross section and may be cylindrical in overall shape. For example, and without limitation the cross section of the first cavity may have a constant radius with respect to the height. The cylindrical shape of the first cavity reduces the wave reflections and the occurrence of standing waves. In some embodiments, the first cavity may have a constant radius with respect to the height and top may be hemispherical or conical cover. The outer wall of the enclosure 1501 may be cuboid, cylindrical, apodized pentagon, patterned walls hemispherical in shape or any other arbitrary shape. Similarly, the second cavity 1503 may be cuboid, cylindrical, apodized pentagon, patterned walls hemispherical in shape or any other arbitrary shape.

FIG. 13B shows a top down view of a two-enclosure MEMS device package with round cavity and enclosure for the MEMS device according to an aspect of the present disclosure. The first enclosure 1512 may have both a hemispherical outer enclosure wall and a round internal cavity 1514 wall. The MEMS device 1504 is located within the hemispherical cavity 1514 of the first enclosure 1512 and the hemispherical shape of the cavity of the first enclosure helps to reduce standing wave propagation. The second enclosure 1513 has a cavity 1515 with an ASIC 1505 located therein. The shape of the second cavity 1515 is show as cuboid or a parallelepiped but aspects of the disclosure are not so limited and the cavity may be for example and without limitation cylindrical, hemispherical or irregularly shaped.

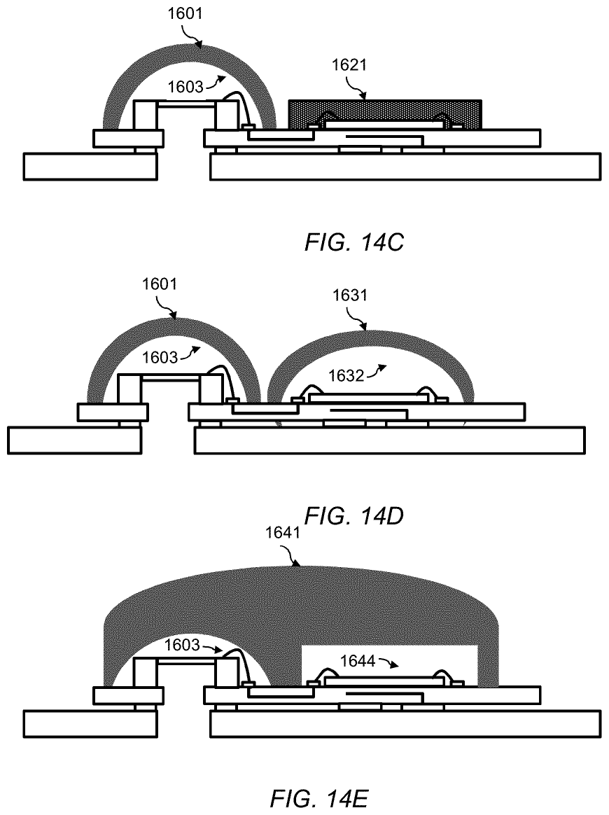

FIG. 14A depicts a side view of a two-enclosure MEMS device package with hemispherical cavity and enclosure according to aspects of the present disclosure. As shown, the MEMS device package includes a hemispherical cavity 1603 wherein the MEMS device is located and a quadrilateral parallelepiped cavity 1604 wherein the ASIC may be located. The outer enclosure of the hemispherical cavity 1601 is also hemispherical. Similarly, the outer enclosure for the ASIC 1602 is also a quadrilateral parallelepiped. FIG. 14B depicts a side view of a single enclosure MEMS device package with hemispherical cavity and enclosure according to aspects of the present disclosure. As shown the MEMS packages include a hemispherical cavity 1603 wherein the MEMS device is located and a quadrilateral parallelepiped cavity 1604 wherein the ASIC may be located. The outer enclosure, housing both the MEMS device cavity 1603 and the ASIC cavity 1604 is quadrilateral parallelepiped shaped 1611. FIG. 14C depicts a side view of a two-enclosure MEMS device package with hemispherical cavity and an infill cavity according to aspects of the present disclosure. The MEMS device package as shown includes a hemispherical cavity 1603 for the MEMS device with a hemispherical outer enclosure 1601. The second enclosure 1621 wherein the ASIC is located is an infill over top the ASIC and other components. The other components may be gyroscopes, accelerometers or passive electric components. While the second enclosure 1621 is shown as being cuboid, it should be understood that the enclosure may be any shape including irregular shapes sufficient to cover the ASIC.

FIG. 14D depicts a side view of a two-enclosure MEMS device package with two hemispherical cavities and enclosure according to aspects of the present disclosure. Both the MEMS device cavity 1603 and the ASIC cavity 1632 are hemispherical as shown.

Additionally the first enclosure wherein the MEMS device is located 1601 is hemispherical and the second enclosure wherein the ASIC is located 1631 is hemispherical. While the depicted embodiments include a hemispherical cavity for the ASIC 1632 and MEMS cavity 1603, aspects of the present disclosure are not so limited and the shape of the cavities 1632, 1603 may be any shape including quadrilateral parallelepiped or an irregular shape.

FIG. 14E depicts a side view of a single dome-topped enclosure MEMS device package with two hemispherical cavities and enclosure, according to aspects of the present disclosure. As shown the overall shape of the enclosure 1641 is irregular having a domed top with flat sides. The interior cavities for the MEMS device 1603 and the ASIC 1604 may be hemispherical and quadrilateral parallelepiped respectively or any shape as discussed above. The shape of the outer enclosure 1641 is not limited to the shape shown and may be any three-dimensional shape such as cylindrical, pyramidal, or cuboid with a textured top. Additionally, the cavities shown are not limited to the quadrilateral and hemispherical shapes discussed and may include other irregular shapes with unique cavity geometries. Such as hemispheres with square sides or cuboids with triangular protrusions, or square sides with triangular tops, or curved tops or textured tops, the irregular shapes may be chosen to accommodate the MEMS device, ASIC, or other components in their respective cavities.

All cited references are incorporated herein by reference in their entirety. In addition to any other claims, the applicant(s)/inventor(s) claim each and every embodiment of the invention described herein, as well as any aspect, component, or element of any embodiment described herein, and any combination

While the above is a complete description of the preferred embodiments of the present invention, it is possible to use various alternatives, modifications, and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A” or “An” refers to a quantity of one or more of the item following the article, except where expressly stated otherwise. The appended claims are not to be interpreted as including means-plus-function limitations, unless such a limitation is explicitly recited in a given claim using the phrase “means for”. Any element in a claim that does not explicitly state “means for” performing a specified function, is not to be interpreted as a “means” or “step” clause as specified in 35 USC § 112, ¶6.

What is claimed is:

1. A micromechanical system (MEMS) device package comprising;
a substrate;
a first enclosure including a first cavity, coupled to the substrate and wherein a transverse dimension of the first cavity relative to the substrate is configured to reduce undesirable acoustic modes within the first cavity, where in the first cavity comprises an acoustic port;
a MEMS device located inside the first cavity;
an Application Specific Integrated Circuit (ASIC) communicatively coupled to the MEMS device and located outside the first cavity.

2. The MEMS device package of claim 1 wherein a cross section of the first cavity has a constant radius with respect to the height to reduce the occurrence of undesirable acoustic modes.

3. The MEMS device package of claim 1 wherein the first enclosure further includes a second cavity and wherein the ASIC is located inside the second cavity.

4. The MEMS device package of claim 3 wherein the second cavity has an irregular shape.

5. The MEMS device package of claim 3, wherein a shape of the second cavity is substantially a parallelepiped.

6. The MEMS device package of claim 3, wherein first and second enclosures have separate metal walls and separate lids.

7. The MEMS device of claim 3, wherein first and second enclosures have separate metal walls and common lid.

8. The MEMS device package of claim 1 wherein the substrate forms a side of the first enclosure and a side of the first cavity.

9. The MEMS device package of claim 1 wherein the first enclosure includes any combination of metal sides, molded sides, or laminate sides and a metal cap, molded cap, or laminate cap.

10. The MEMS device package of claim 1 further comprising a second enclosure including at least a second cavity, coupled to the substrate wherein the ASIC is located inside the second cavity

11. The MEMS device package of claim 10 wherein the second enclosure includes any combination of metal sides, molded sides, or laminate sides and a metal cap, molded cap, or laminate cap.

12. The MEMS device package of claim 10 wherein the second cavity has an irregular shape.

13. The MEMS device package of claim 1 wherein the MEMS device is an Ultrasonic Transducer.

14. The MEMS device package of claim 1, wherein the MEMS device is disposed over the acoustic port,

15. The MEMS device package of claim 1, further comprising an accelerometer or a gyroscope in the second cavity.

16. The MEMS device package of claim 15, where in the ASIC is shared with the accelerometer or gyroscope.

17. The MEMS device package of claim 1 wherein the MEMS device is coupled to the substrate.

18. The MEMS device package of claim 1 wherein a dimension of the cavity is chosen to reduce reflections of wavelengths corresponding to a characteristic frequency of a mode of oscillation of the MEMS device.

19. The MEMS device package of claim 1 wherein the first cavity is hemispherical in shape.

20. The MEMS device package of claim 1, the first enclosure having a curved inner wall of the cavity and an outer wall, wherein the outer cavity wall is substantially planar.

21. The MEMS device package of claim 1, where in the MEMS device is electrically connected to the substrate by wirebonds.

22. The MEMS device package of claim 1, where in the second enclosure comprises over molded ASIC.

23. The MEMS device package of claim 1 wherein the first cavity has an irregular shape.

24. The MEMS device package of claim 1, wherein a thickness of the MEMS device package is less than a thickness of the substrate, the enclosure, the MEMS device and the ASIC combined.
